(19) United States
(12) Patent Application Publication
(10) Pub. No.: US 2026/0129838 A1
(43) Pub. Date: May 7, 2026

(54) MEMORY DEVICE INCLUDING GATE CAPPING LAYER

(71) Applicant: SK hynix Inc., Gyeonggi-do (KR)

(72) Inventors: Sung Soo KIM, Gyeonggi-do (KR); Na Hye WON, Gyeonggi-do (KR); Seung Hee KIM, Gyeonggi-do (KR)

(21) Appl. No.: 19/208,547

(22) Filed: May 14, 2025

(30) Foreign Application Priority Data
Nov. 4, 2024 (KR) 10-2024-0153982

(51) Int. Cl. H10B 12/00

(52) U.S. Cl. CPC H10B 12/34; H10B 12/0335; H10B 12/053; H10B 12/485

(57) ABSTRACT

According to an embodiment of the present disclosure, a memory device may include a substrate including an active area; a word line embedded in the substrate, and crossing the active area; a gate insulating layer surrounding a side surface and a lower surface of the word line; a gate capping layer disposed on inner side surfaces of the gate insulating layer on the word line; and a bit line contact contacting the active area that is disposed between word lines, and having a side surface that faces the gate capping layer and is concave toward a center of the bit line contact.

### CROSS-REFERENCE TO RELATED APPLICATION

The present application claims priority under 35 U.S.C. § 119(a) to Korean Patent Application No. 10-2024-0153982 filed on Nov. 4, 2024, which is incorporated herein by reference in its entirety.

### BACKGROUND

### 1. Technical Field

An embodiment of the present disclosure relates generally to a memory device, and more particularly, to a memory device including a gate capping layer.

### 2. Related Art

Memory devices are attracting significant interest as an important element in the electronics industry thanks to their characteristics such as miniaturization, multifunctionality and low manufacturing costs. As the electronics industry has developed rapidly, memory devices are becoming increasingly highly integrated. In order for high integration of memory devices, the line width of wirings included in the memory devices is gradually decreasing and the size of memory cells is becoming smaller. Due to this fact, the difficulty of a process for forming the memory cells is increasing.

### SUMMARY

Various embodiments of the present disclosure are directed to a memory device capable of preventing a process defect from occurring during the manufacturing process of the memory device.

According to an embodiment of the present disclosure, a memory device may include a substrate including an active area; a word line embedded in the substrate, and crossing the active area; a gate insulating layer surrounding a side surface and a lower surface of the word line; a gate capping layer disposed on inner side surfaces of the gate insulating layer on the word line; and a bit line contact contacting the active area that is disposed between word lines, and having a side surface that faces the gate capping layer and is concave toward a center of the bit line contact.

According to an embodiment of the present disclosure, a memory device may include a substrate including an active area; a word line embedded in the substrate, and crossing the active area; a gate insulating layer surrounding a side surface and a lower surface of the word line; a gate capping layer disposed on inner side surfaces of the gate insulating layer on the word line; a buffer layer disposed on the gate capping layer; and a bit line contact including a first section that contacts the active area between word lines and a second section that is located on the first section and is continuous to the first section, wherein an angle formed by a side surface of the first section with an upper surface of the substrate is different from an angle formed by a side surface of the second section with the upper surface of the substrate.

According to an embodiment of the present disclosure, a memory device may include a substrate including an active area; a bit line contact contacting the active area, having a side surface that is concave toward a center of the bit line contact, and including a first section and a second section that is located on the first section and is continuous to the first section; a gate capping layer located on a side surface of the first section of the bit line contact; and a buffer layer located on a side surface of the second section of the bit line contact.

According to an embodiment of the present disclosure, it is possible to prevent a process defect from occurring during the manufacturing process of a memory device.

These and other features and advantages of the embodiments of the present disclosure will become better understood from the following embodiments in conjunction with the following description. BRIEF

### DESCRIPTION OF THE DRAWINGS

FIG. 1 is a view illustrating a planar structure of a memory device according to an embodiment of the present disclosure.

FIG. 2 is a view illustrating a cross-sectional structure taken along line I-I′ of FIG. 1.

FIG. 3A is an enlarged view of a part 10 of FIG. 2.

FIG. 3B is another enlarged view of the part 10 of FIG. 2.

FIG. 4 is a view illustrating a cross-sectional structure taken along line II-II′ of FIG. 1.

FIG. 5 is a view illustrating a cross-sectional structure taken along line III-III′ of FIG. 1.

FIG. 6 is a view illustrating another cross-sectional structure taken along line I-I′ of FIG. 1.

FIG. 7A is an enlarged view of a part 20 of FIG. 6.

FIG. 7B is another enlarged view of the part 20 of FIG. 6.

FIG. 8 is a view illustrating another cross-sectional structure of the part indicated by the line II-II′ of FIG. 1.

FIG. 9 is a view illustrating another cross-sectional structure of the part indicated by the line III-III′ of FIG. 1.

FIG. 10 to FIG. 16 are views illustrating a method for forming a memory device according to an embodiment of the present disclosure.

FIG. 17 to FIG. 20 are views illustrating another method for forming a memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe the technical concepts of the present disclosure. It is noted, however, that the embodiments in accordance with the technical concepts of the present disclosure may be carried out in various other forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one embodiment, and the second element may be named as a first element in another embodiment.

In the description, when an element included in an embodiment is described in singular form, the element may be interpreted to include a plurality of elements performing the same or similar functions.

In the accompanying drawings, three directions that are parallel to the upper surface of a substrate are defined as a first direction FD, a second direction SD and a third direction TD, respectively, and a direction that vertically protrudes from the upper surface of the substrate is defined as a fourth direction VD. The first direction FD and the second direction SD may be substantially perpendicular to each other. The fourth direction VD is a direction that is perpendicular to the first direction FD, the second direction SD and the third direction TD. In the following description, the term ‘vertical’ or ‘vertical direction’ will be used as substantially the same meaning as the fourth direction VD. In the drawings, a direction indicated by an arrow and a direction opposite thereto represent the same direction.

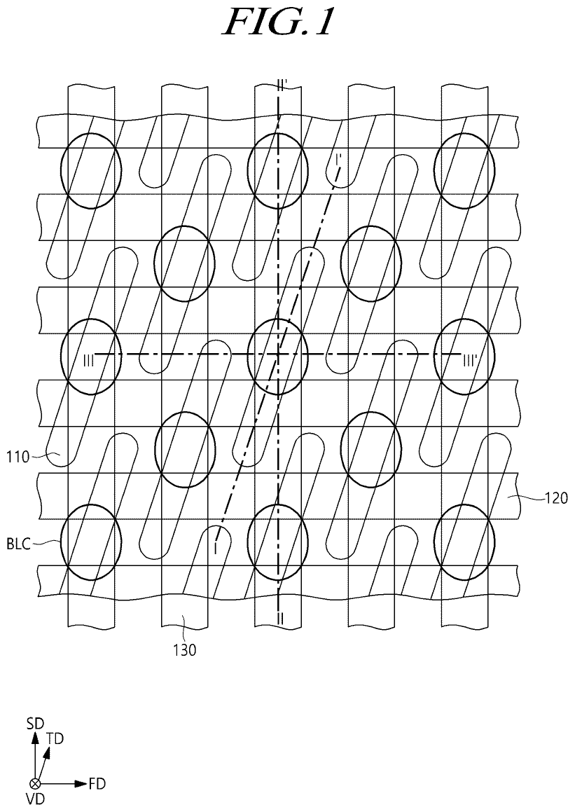

FIG. 1 is a view illustrating a planar structure of a memory device according to an embodiment of the present disclosure.

Referring to FIG. 1, the memory device according to an embodiment of the present disclosure includes active areas 110, word lines 120, bit line structures 130, and bit line contacts BLC. The word lines 120 cross the active areas 110 and extend in the first direction FD. The word lines 120 are disposed parallel to each other in the second direction SD. The word lines 120 are spaced apart from each other at a regular interval in the second direction SD. In an embodiment as shown in FIG. 1, two corresponding word lines 120 may cross one active area 110.

The bit line structures 130 extend in the second direction SD. The bit line structures 130 are disposed parallel to each other in the first direction FD. The bit line structures 130 are spaced apart from each other at a regular interval in the first direction FD. The bit line structures 130 cross the active areas 110. The bit line structures 130 cross the word lines 120. The bit line structures 130 may be orthogonal to the word lines 120. In an embodiment as shown in FIG. 1, each active area 110 is crossed by one bit line structure 130.

The bit line contacts BLC are disposed to overlap the active areas 110, respectively. Each bit line contact BLC may correspond to one active area 110. The bit line contact BLC may be located in the vicinity of the center of the active area 110. The bit line contact BLC is located between word lines 120. The bit line contact BLC overlaps with a corresponding bit line structure 130 in the second direction SD. FIG. 1 illustrates that the bit line contact BLC may have an oval shape when viewed in a plan view, however the shape of the bit line contact BLC is not limited thereto.

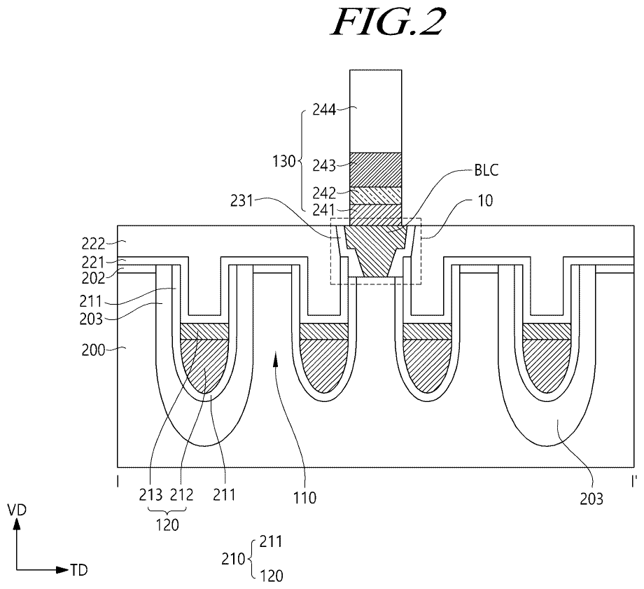

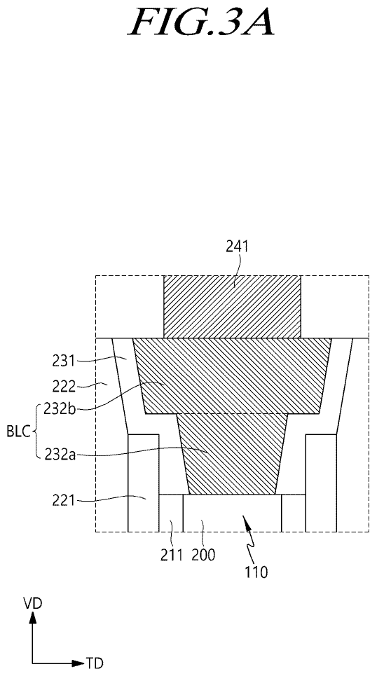

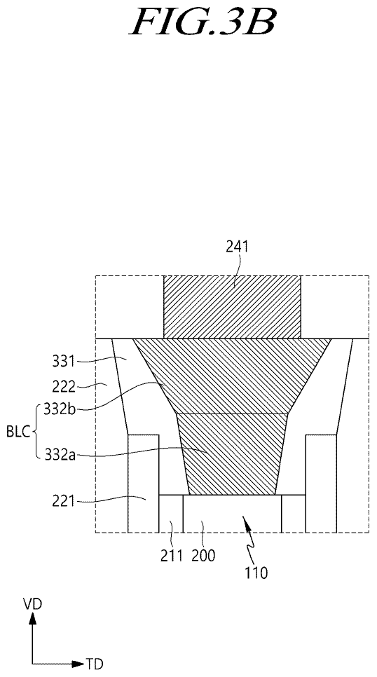

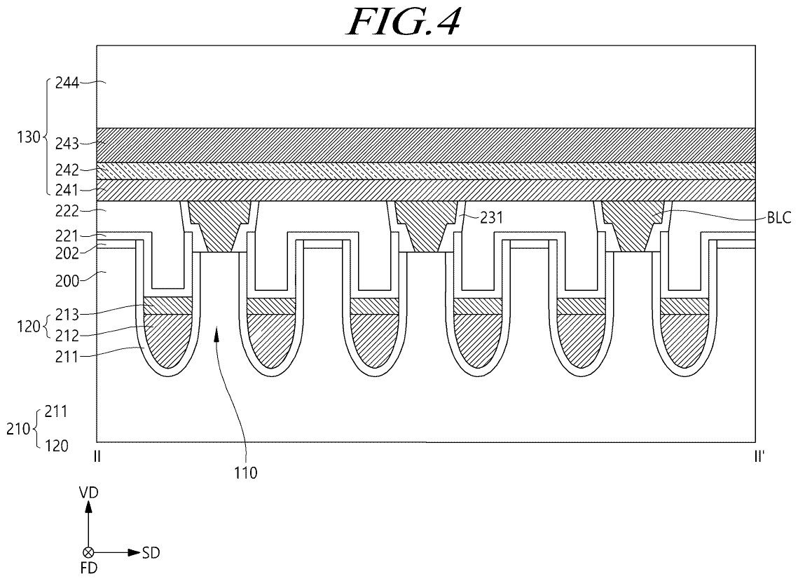

FIG. 2 is a view illustrating a cross-sectional structure taken along line I-I′ of FIG. 1. FIG. 3A is an enlarged view of a part 10 of FIG. 2. FIG. 3B is another enlarged view of the part 10 of FIG. 2. FIG. 4 is a view illustrating a cross-sectional structure taken along line II-II′ of FIG. 1.

Referring to FIG. 2 to FIG. 4, the memory device according to an embodiment of the present disclosure includes a substrate 200, an isolation layer 203, a gate structure 210, a second insulating layer 202, a gate capping layer 221, a buffer layer 222, a first spacer 231, the bit line contact BLC, and the bit line structure 130.

The substrate 200 may include a semiconductor substrate such as a silicon wafer or a silicon-on-insulator (SOI) wafer. The substrate 200 may include a III-V group semiconductor substrate, for example, a compound semiconductor substrate such as gallium arsenide (GaAs). The substrate 200 may include monocrystalline silicon, polysilicon, amorphous silicon, monocrystalline silicon germanium, polycrystalline silicon germanium, carbon-doped silicon or a combination thereof.

The isolation layer 203 delimits the active areas 110 and is disposed in the substrate 200. The active areas 110 may be spaced apart from each other in the first direction FD, the second direction SD and the third direction TD by the isolation layer 203. The active areas 110 and the isolation layer 203 may be formed using a trench isolation technology such as shallow trench isolation (STI). According to an embodiment of the present disclosure, the active areas 110 may include monocrystalline silicon that has P-type impurities. The P-type impurities may include, for example, B, BF, BF2 or a combination thereof. The isolation layer 203 may include a single layer or a multilayer. According to an embodiment of the present disclosure, the isolation layer 203 may include at least two selected from the group consisting of Si, O, N, C and H. For example, the isolation layer 203 may include, for example, silicon oxide, silicon nitride, silicon oxynitride, low-k dielectric, high-k dielectric or a combination thereof.

The gate structure 210 may be embedded in the substrate 200. The gate structure 210 may cross the active area 110 in the first direction FD. The gate structure 210 may include a gate insulating layer 211 and the word line 120. The gate insulating layer 211 may surround the side surface and the lower surface of the word line 120. The word line 120 may include an upper word line 213 and a lower word line 212. The word line may be disposed to fill a lower area of the gate structure 210. An upper surface of the word line 120 may be located at a lower level than the upper surface of the active area 110 in a vertical direction.

The gate insulating layer 211 may include, for example, silicon oxide, silicon nitride, silicon oxynitride, high-k dielectric or a combination thereof. The word line 120 may include a conductive material such as, for example, metal, metal oxide, metal nitride, metal silicide, polysilicon, conductive carbon or a combination thereof. The upper word line 213 may include a material different from a material that forms the lower word line 212. According to an embodiment of the present disclosure, the upper word line 213 may include a low work function material, while the lower word line 212 may include a high work function material. For example, According to an embodiment of the present disclosure, the upper word line 213 may include doped polysilicon, and the lower word line 212 may include titanium nitride.

The second insulating layer 202 may be disposed on the active area 110. According to an embodiment of the present disclosure, the second insulating layer 202 may include a material the same as a material that forms the gate insulating layer 211.

The gate capping layer 221 may be disposed on the second insulating layer 202. The gate capping layer 221 may be disposed along the steps of underlying layers. The gate capping layer 221 may conformally cover the inner side surfaces of the gate insulating layer 211 at an upper area of the gate structure 210 which is exposed by the word lines 120. The gate capping layer 221 may be disposed to cover the upper surface of the second insulating layer 202. The gate capping layer 221 may be disposed on the inner side surfaces of the gate insulating layer 211 and the upper surface of the word line 120. According to an embodiment of the present disclosure, the gate capping layer 221 may cover the entirety of the upper surface of the word line 120. The gate capping layer 221 may include, for example, silicon oxide, silicon nitride, silicon oxynitride, low-k dielectric, high-k dielectric or a combination thereof. According to an embodiment of the present disclosure, the gate capping layer 221 may include silicon nitride.

The buffer layer 222 is disposed on the gate capping layer 221. The buffer layer 222 is disposed to fill the space between the inner side surfaces of the gate capping layer 221 that is located on the gate insulating layer 211. The lowermost surface of the buffer layer 222 is disposed at a level lower than the upper surface of the active area 110. According to an embodiment of the present disclosure, the lowermost surface of the buffer layer 222 may contact the upper surface of the gate capping layer 221 in an area between the inner side surfaces of the gate capping layer 221. The buffer layer 222 may include, for example, silicon oxide, silicon nitride, silicon oxynitride, low-k dielectric, high-k dielectric or a combination thereof. The buffer layer 222 may include a material that has an etching selectivity with respect to a first bit line 241. According to an embodiment of the present disclosure, the buffer layer 222 may include, for example, silicon oxide. According to an embodiment of the present disclosure, the buffer layer 222 may include a material, such as, for example, an ultra low temperature oxide (ULTO) or a spin-on dielectric (SOD), depending on which deposition method is used.

Referring to FIG. 1, FIG. 2 and FIG. 4, in the second direction SD and the third direction TD, the bit line contact BLC is disposed between word lines 120. The bit line contact BLC penetrates the buffer layer 222, the gate capping layer 221 and the second insulating layer 202 in the vertical direction to contact the active area 110. According to an embodiment of the present disclosure, the width of the bit line contact BLC in the second direction SD and the third direction TD may decrease in a vertical downward direction. According to an embodiment of the present disclosure, the side surface of the bit line contact BLC that faces the gate capping layer 221 may define a shape that is concave toward the center of the bit line contact BLC. The bit line contact BLC may include a conductive material such as, for example, metal, metal oxide, metal nitride, metal silicide, polysilicon, conductive carbon or a combination thereof.

The first spacer 231 may surround the side surface of the bit line contact BLC. The outer side surface of the first spacer 231 may contact the buffer layer 222 and the gate capping layer 221. The lower surface of the first spacer 231 may contact the top surface of the gate insulating layer 211 and the top surface of the active area 110. The first spacer 231 may include, for example, silicon oxide, silicon nitride, silicon oxynitride, low-k dielectric, high-k dielectric or a combination thereof.

Referring to FIG. 2 and FIG. 4, the bit line structure 130 is disposed on the bit line contact BLC and the buffer layer 222. The bit line structure 130 extends in the second direction SD. The bit line structure 130 may include the first bit line 241, a second bit line 242, a third bit line 243 and a bit line capping layer 244 stacked over each other. The first bit line 241, the second bit line 242, the third bit line 243 and the bit line capping layer 244 are sequentially stacked in the vertical direction. The first bit line 241, the second bit line 242 and the third bit line 243 may constitute one bit line. The first bit line 241, the second bit line 242 and the third bit line 243 may include a conductive material such as, for example, metal, metal oxide, metal nitride, metal silicide, polysilicon, conductive carbon or a combination thereof. The bit line capping layer 244 may include, for example, silicon oxide, silicon nitride, silicon oxynitride, low-k dielectric, high-k dielectric or a combination thereof. According to an embodiment of the present disclosure, the first bit line 241 may be polysilicon, the second bit line 242 may be metal silicide, and the third bit line 243 may be metal. According to an embodiment of the present disclosure, the bit line capping layer 244 may be silicon nitride.

Referring to FIG. 3A, the bit line contact BLC may include a first section 232a and a second section 232b formed over the first section. The bit line contact BLC may include monocrystalline silicon formed by a selective epitaxial growth (SEG) process, doped (for example, phosphorus-doped) polysilicon, or a combination thereof. For example, the first section 232a may include monocrystalline silicon, and the second section 232b may include doped polysilicon. The second section 232b may be disposed on the first section 232a, and may be continuous to the first section 232a. According to an embodiment of the present disclosure, the area of the upper surface of the first section 232a may be smaller than the area of the lower surface of the second section 232b. According to an embodiment of the present disclosure, at least a portion of the lower surface of the second section 232b might not overlap the first section 232a in the vertical direction.

The lower surface of the first section 232a may contact the upper surface of the active area 110 of the substrate 200. According to an embodiment of the present disclosure, the width of the lower surface of the first section 232a in the third direction TD may be smaller than the width, in the third direction TD, of the upper surface of the active area 110 that contacts the first section 232a of the bit line contact BLC. The upper surface of the second section 232b may contact the first bit line 241. According to an embodiment of the present disclosure, the width of the upper surface of the second section 232b in the third direction TD may be larger than the width of the lower surface of the first bit line 241 in the third direction TD. According to an embodiment of the present disclosure, at least a portion of the lower surface of the second section 232b might not contact the upper surface of the first section 232a. According to an embodiment of the present disclosure, the angle that the side surface of the first section 232a forms with the upper surface of the substrate 200 may be different from the angle that the side surface of the second section 232b forms with the upper surface of the substrate 200.

The first spacer 231 may surround the side surface of the first section 232a of the bit line contact BLC. The first spacer 231 may surround and contact the side surface and an outer portion of the lower surface of the second section 232b of the bit line contact BLC.

Referring to FIG. 3B, the bit line contact BLC may include a first section 332a and a second section 332b. The second section 332b may be disposed on the first section 332a, and may be continuous to the first section 332a. According to an embodiment of the present disclosure, the area of the upper surface of the first section 332a may be the same as the area of the lower surface of the second section 332b. According to an embodiment of the present disclosure, the angle that the side surface of the first section 332a forms with the upper surface of the substrate 200 may be larger than the angle that the side surface of the second section 332b forms with the upper surface of the substrate 200.

A first spacer 331 may surround and contact the side surface of the first section 332a and may also surround and contact the side surface of the second section 332b of the bit line contact BLC.

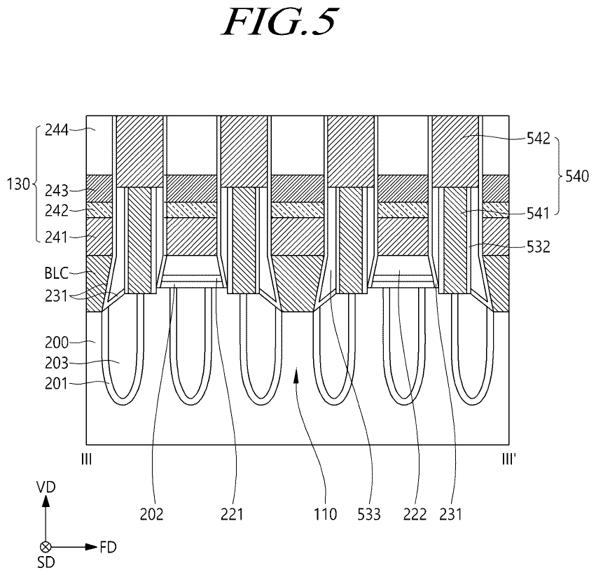

FIG. 5 is a view illustrating a cross-sectional structure taken along line III-III′ of FIG. 1.

Referring to FIG. 5, the memory device according to an embodiment of the present disclosure may include the substrate 200, the isolation layer 203, the second insulating layer 202, the gate capping layer 221, the buffer layer 222, the first spacer 231, the bit line contact BLC, the bit line structure 130, a second spacer 532, a third spacer 533, and a contact plug 540.

The contact plug 540 includes a lower contact plug 541 and an upper contact plug 542 that is disposed on the lower contact plug 541. The lower contact plug 541 and the upper contact plug 542 may include a conductive material such as, for example, metal, metal oxide, metal nitride, metal silicide, polysilicon, conductive carbon or a combination thereof.

Referring to FIG. 1 and FIG. 5, the bit line contact BLC, the contact plug 540 and the second insulating layer 202 may be disposed on the active area 110 and the isolation layer 203 of the substrate 200. Each of the bit line contact BLC and the contact plug 540 may overlap with the active area 110 in the vertical direction. The bit line contact BLC and the contact plug 540 may contact the active area 110. According to an embodiment of the present disclosure, two contact plugs 540 may be located between bit line contacts BLC in the first direction FD. Between the contact plugs 540, the second insulating layer 202, the gate capping layer 221 and the buffer layer 222 may be located under the bit line structure 130. The second insulating layer 202, the gate capping layer 221 and the buffer layer 222 may overlap with the isolation layer 203 in the vertical direction. The bit line structure 130 may be disposed on the bit line contact BLC. The bit line structure 130 and the contact plug 540 may be disposed alternately in the first direction FD.

The first spacer 231 may be disposed on the side surfaces of the bit line contact BLC and the bit line structure 130. The first spacer 231 may be disposed between the upper contact plug 542 and the bit line structure 130. The second spacer 532 may be disposed on the side surface of the lower contact plug 532. The third spacer 533 may be disposed between the first spacer 231 and the second spacer 532. The first spacer 231 may extend between the isolation layer 203 and the third spacer 533. The first spacer 231 may extend between the second insulating layer 202, the gate capping layer 221 and the buffer layer 222 on one side and the third spacer 533 on the other side.

The first spacer 231, the second spacer 532 and the third spacer 533 may include a dielectric material such as, for example, silicon oxide, silicon nitride, silicon oxynitride, low-k dielectric, high-k dielectric, or a combination thereof. According to an embodiment of the present disclosure, the first spacer 231 may be silicon nitride.

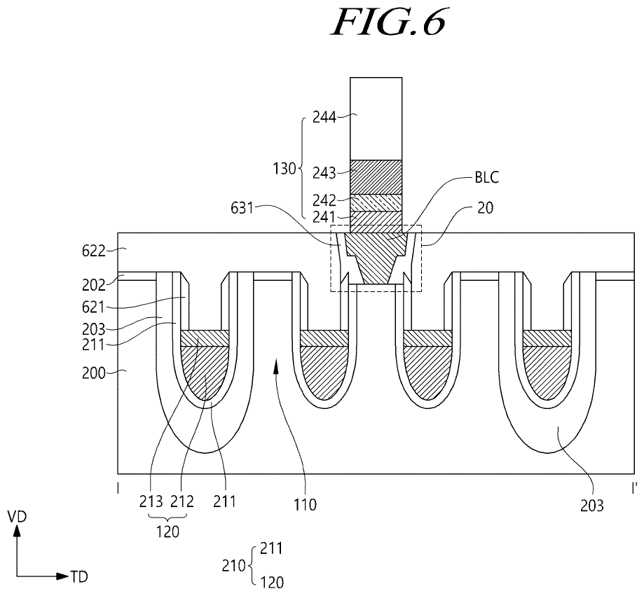

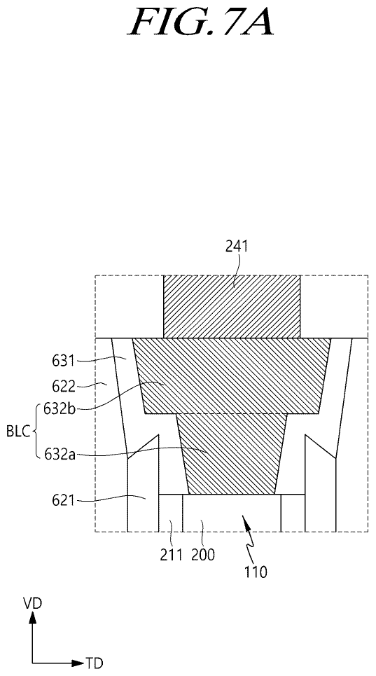

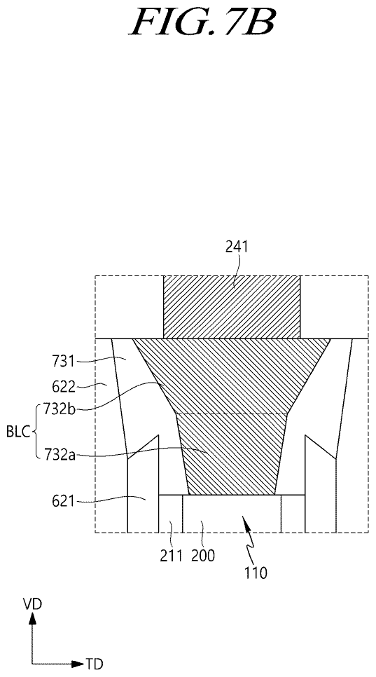

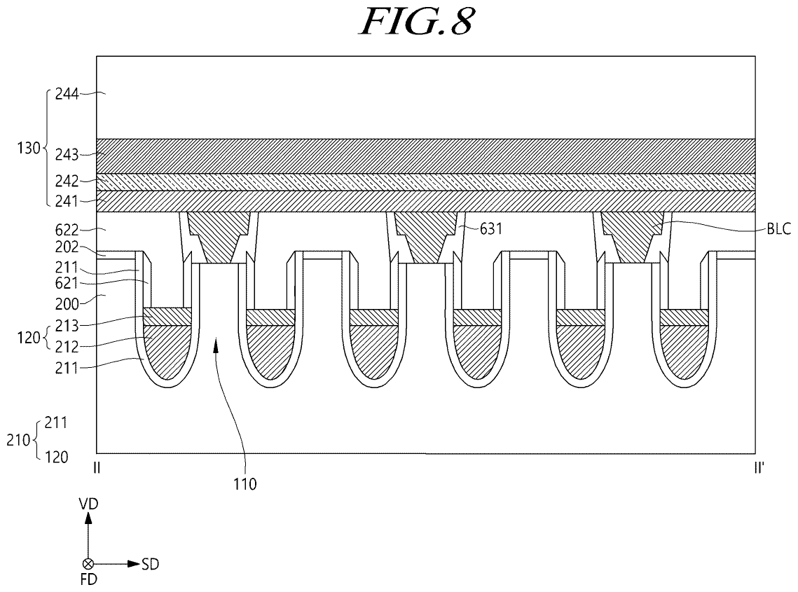

FIG. 6 is a view illustrating another cross-sectional structure taken along line I-I′ of FIG. 1. FIG. 7A is an enlarged view of a part 20 of FIG. 6. FIG. 7B is another enlarged view of the part 20 of FIG. 6. FIG. 8 is a view illustrating another cross-sectional structure of the part indicated by the line II-II′ of FIG. 1.

In describing the following embodiments, description of components that are substantially the same as those in the previous embodiments will be omitted.

Referring to FIG. 6 to FIG. 8, the memory device according to an embodiment of the present disclosure may include a substrate 200, an isolation layer 203, a gate structure 210, a second insulating layer 202, a gate capping layer 621, a buffer layer 622, a first spacer 631, the bit line contact BLC, and the bit line structure 130.

The gate capping layer 621 is disposed on the upper surface of the word line 120 and the inner side surfaces of the gate insulating layer 211. According to an embodiment of the present disclosure, the gate capping layer 621 may be disposed in a partial area on the upper surface of the word line 120 and may expose at least a portion of the upper surface of the word line 120. According to an embodiment of the present disclosure, the upper surface of the gate capping layer 621 may form an angle between 0 and 90 degrees with the upper surface of the substrate 200.

Referring to FIG. 6 and FIG. 8, the gate capping layer 621 might not be disposed on the upper surface of the second insulating layer 202. According to an embodiment of the present disclosure, the upper surface of the gate capping layer 621 may be located at the same level as the upper surface of the second insulating layer 202 or at a level lower than the upper surface of the second insulating layer 202 in the vertical direction.

The buffer layer 622 may be disposed on the second insulating layer 202 and the top surface of the word line 120 that is exposed by the gate capping layer 621. The buffer layer 622 may be disposed to fill the space between the inner side surfaces of the gate capping layer 621 that is located on the gate insulating layer 211. The lowermost surface of the buffer layer 622 is disposed at a level lower than the upper surface of the active area 110. In an embodiment as shown in FIG. 6, the lowermost surface of the buffer layer 622 may contact the upper surface of the word line 120 in an area between the inner side surfaces of the gate capping layer 221.

Referring to FIG. 1, FIG. 6 and FIG. 8, the bit line contact BLC is disposed between the word lines 120 in the second direction SD and the third direction TD. The bit line contact BLC penetrates the buffer layer 622 and the second insulating layer 202 in the vertical direction to contact the upper surface of the active area 110. In an embodiment as shown in FIG. 6, the width of the bit line contact BLC in the second direction SD and the third direction TD may decrease in a vertical downward direction. According to an embodiment of the present disclosure, the side surface of the bit line contact BLC that faces the gate capping layer 621 may define a shape that is concave toward the center of the bit line contact BLC.

The first spacer 631 may surround the side surface of the bit line contact BLC. The outer side surface of the first spacer 631 may contact the buffer layer 622 and the gate capping layer 621. The lower surface of the first spacer 631 may contact the top surface of the gate insulating layer 211 and also the top surface of the active area 110.

Referring to FIG. 7A, the bit line contact BLC may include a first section 632a and a second section 632b. The second section 632b may be disposed on the first section 632a, and may be continuous to the first section 632a. According to an embodiment of the present disclosure, the area of the upper surface of the first section 632a may be smaller than the area of the lower surface of the second section 632b. According to an embodiment of the present disclosure, at least a portion of the lower surface of the second section 632b might not overlap the first section 632a in the vertical direction.

The first spacer 631 may surround the side surface of the first section 632a of the bit line contact BLC. The first spacer 631 may surround the side surface and a portion of the lower surface of the second section 632b of the bit line contact BLC. According to an embodiment of the present disclosure, the first spacer 631 may contact the lower surface of the second section 632b. According to an embodiment of the present disclosure, the outer side surface of the first spacer 631 may have a shape that is depressed toward the boundary between the first section 632a and the second section 632b of the bit line contact BLC. The gate capping layer 621 may fill a space that is created as the outer side surface of the first spacer 631 is depressed.

Referring to FIG. 7B, the bit line contact BLC may include a first section 732a and a second section 732b. The second section 732b may be disposed on the first section 732a, and may be continuous to the first section 732a. According to an embodiment of the present disclosure, the area of the upper surface of the first section 732a may be the same as the area of the lower surface of the second section 732b. According to an embodiment of the present disclosure, the angle that the side surface of the first section 732a forms with the upper surface of the substrate 200 may be larger than the angle that the side surface of the second section 732b forms with the upper surface of the substrate 200.

A first spacer 731 may surround the side surface of the first section 732a and also the side surface of the second section 732b of the bit line contact BLC. The outer side surface of the first spacer 731 may have a shape that is depressed toward the boundary between the first section 732a and the second section 732b of the bit line contact BLC. The gate capping layer 621 may fill a space that is created as the outer side surface of the first spacer 731 is depressed.

According to an embodiment of the present disclosure, the first spacer 731 and the bit line contact BLC may be formed through a self-aligned contact method using the buffer layer 622 and the gate capping layer 621 as a mask.

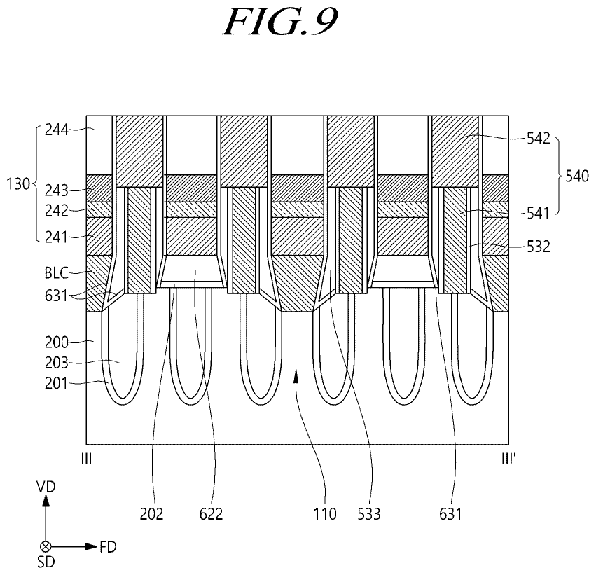

FIG. 9 is a view illustrating another cross-sectional structure taken along the line III-III′ of FIG. 1.

Referring to FIG. 9, the memory device according to an embodiment of the present disclosure may include the substrate 200, the isolation layer 203, the second insulating layer 202, the buffer layer 622, the first spacer 631, the bit line contact BLC, the bit line structure 130, a second spacer 532, a third spacer 533, and a contact plug 540.

In describing the following embodiment, a description of components that are substantially the same as those in the previous embodiments will be omitted.

Referring to FIG. 1 and FIG. 9, the bit line contact BLC, the contact plug 540 and the second insulating layer 202 are disposed on the active area 110 and the isolation layer 203 of the substrate 200. Between two adjacent contact plugs 540, the second insulating layer 202 and the buffer layer may be located under the bit line structure 130. According to an embodiment of the present disclosure, the upper surface of the second insulating layer 202 may contact the lower surface of the buffer layer 622. The first spacer 631 may be disposed on the side surfaces of the second insulating layer 202 and the buffer layer 622.

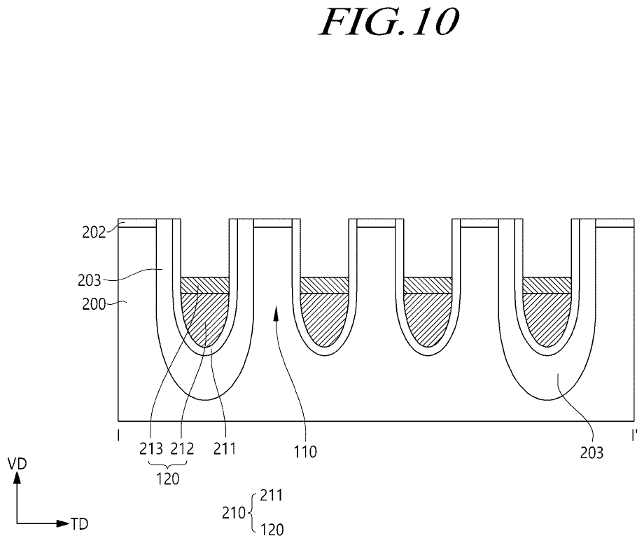

FIG. 10 to FIG. 16 are views illustrating a method for forming a memory device according to an embodiment of the present disclosure.

Referring to FIG. 10, an isolation layer 203 that delimits an active area 110 may be formed.

A gate structure 210 may be formed to cross the active area 110. The gate structure 210 may be formed in the isolation layer 203, and also may be formed in the active area 110 of the substrate 200. After a trench for disposing the gate structure 210 is formed, a gate insulating layer 211 may be formed conformally on the side surface and the lower surface of the trench. A word line 120 may be then formed on the gate insulating layer 211. According to an embodiment of the present disclosure, forming a lower word line 212 and an upper word line 213 may include an etch-back process.

A second insulating layer 202 may be formed on the upper surface of the active area 110. According to an embodiment of the present disclosure, the second insulating layer 202 may include a material that is the same as a material that forms the gate insulating layer 211. According to an embodiment of the present disclosure, the thickness of the second insulating layer 202 may be equal to or less than 75 angstroms.

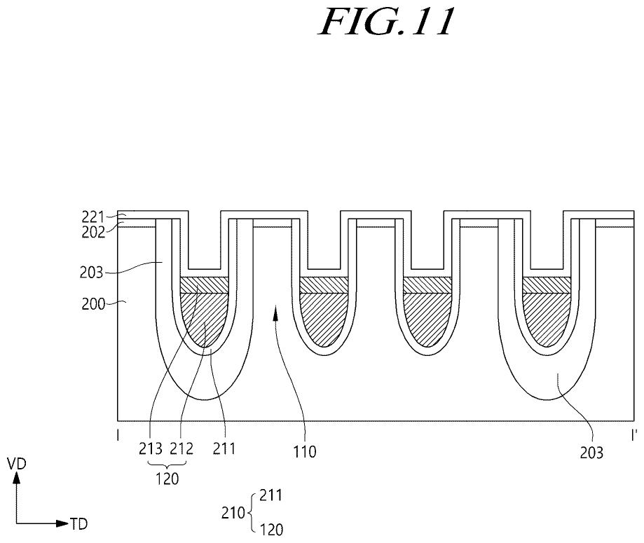

Referring to FIG. 11, a gate capping layer 221 is formed on the second insulating layer 202. The gate capping layer 221 may be disposed along the steps of underlying layers. The gate capping layer 221 may conformally cover the inner side surfaces of the gate insulating layer 211 and the upper surface of the second insulating layer 202. According to an embodiment of the present disclosure, the thickness of the gate capping layer 221 may be equal to or greater than 10 angstroms and equal to or less than 50 angstroms.

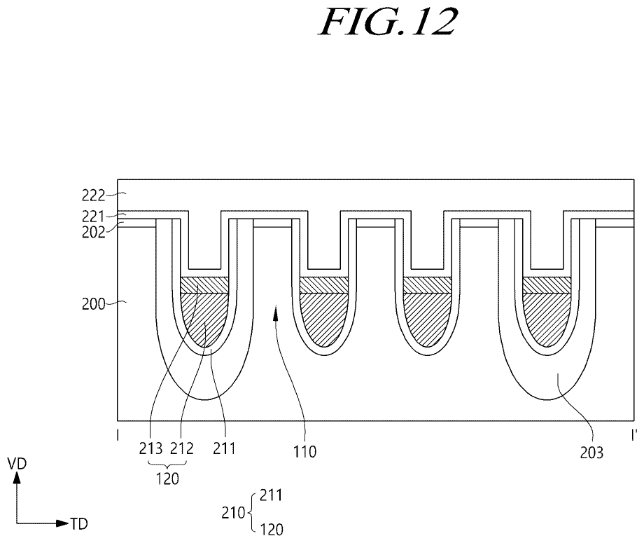

Referring to FIG. 12, a buffer layer 222 may be formed on the gate capping layer 221. The buffer layer 222 may fill the space between the inner side surfaces of the gate capping layer 221. According to an embodiment of the present disclosure, the buffer layer 222 may include a material that is the same as a material that forms the second insulating layer 202.

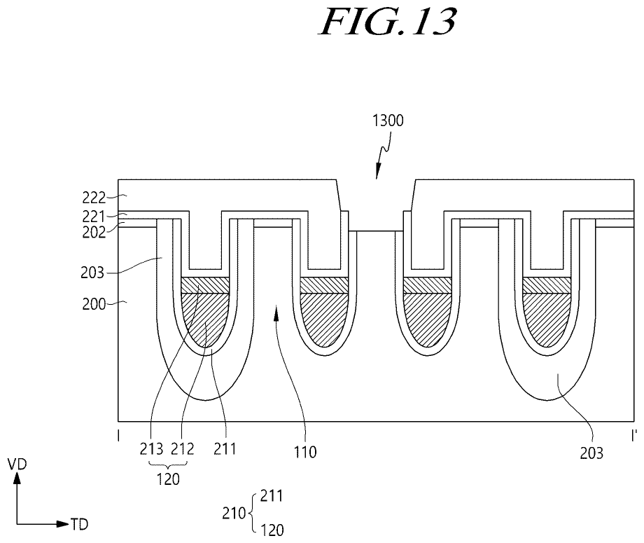

Referring to FIG. 13, a contact hole 1300 that penetrates the buffer layer 222, the gate capping layer 221 and the second insulating layer 202 in the vertical direction may be formed. Forming the contact hole 1300 may include a self-aligned contact etching process using an etching selectivity between oxide and nitride.

According to an embodiment of the present disclosure, the etching process may include a dry etching process for etching oxide. A gas used in the dry etching process may include a material that may increase the etching selectivity between the gate capping layer 221 and the buffer layer 222. According to an embodiment of the present disclosure, a gas used in the dry etching process may include a CxFy-based material with the x and y being natural numbers. A value obtained by dividing y by x may be equal to or greater than 1.5. According to an embodiment of the present disclosure, a gas used in the dry etching process may be hexafluorobutadiene (C4F6).

The contact hole 1300 may expose the upper surface and portions of the side surfaces of the gate capping layer 221, the upper surface of the gate insulating layer 211, and the upper surface of the active area 110. According to an embodiment of the present disclosure, the upper surface of the gate capping layer 221 that is adjacent to the contact hole 1300 may be located at substantially the same level as the upper surface of the gate capping layer 221 that is disposed on the second insulating layer 202.

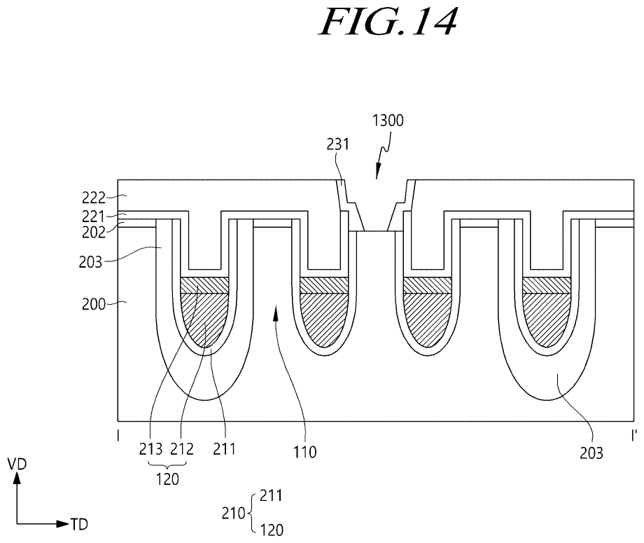

Referring to FIG. 14, a first spacer 231 may be formed on the sidewall of the contact hole 1300. The first spacer 231 surrounds the sidewall of the contact hole 1300. The first spacer 231 may be formed along the steps of underlying layers. The inner side surface of the first spacer 231 may have a shape that is concave toward the center of the contact hole 1300.

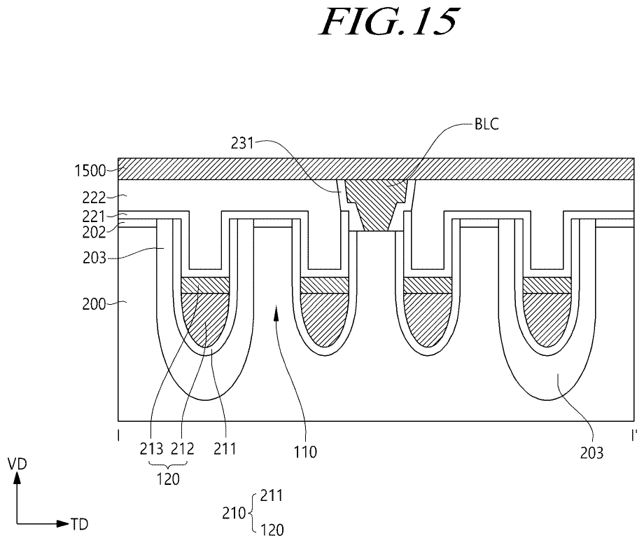

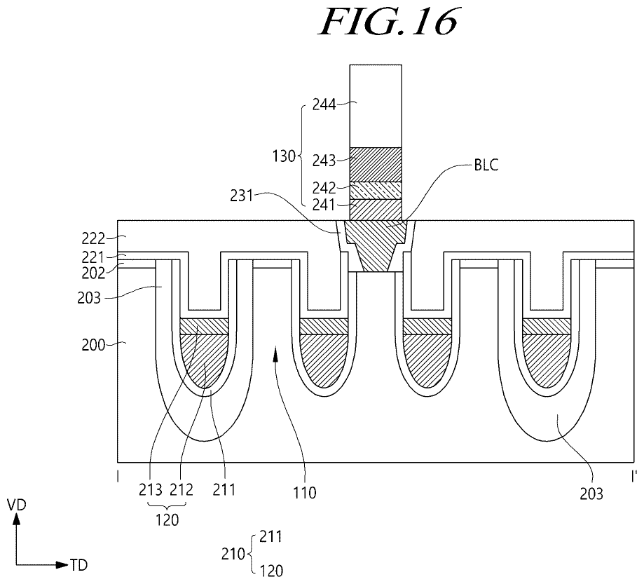

Referring to FIG. 15 and FIG. 16, a bit line contact BLC is formed to fill the inside of the contact hole 1300. Forming the bit line contact BLC may include a deposition process and an etch-back process. For example, forming the bit line contact BLC may include depositing a conductive material such as, for example, tungsten (W), to fill the contact hole 1300. This can be done through methods such as, for example, Chemical Vapor Deposition (CVD) or Physical Vapor Deposition (PVD). Following the deposition, the etch back process may remove any excess material that remains after the deposition.

A first bit line pattern 1500 may then be formed on the bit line contact BLC, the first spacer 231 and the buffer layer 222. A first bit line 241 may be formed by etching the first bit line pattern 1500. A second bit line 242, a third bit line 243 and a bit line capping layer 244 are sequentially formed on the first bit line 241. According to an embodiment of the present disclosure, processes of forming the second bit line 242 and the third bit line 243 may include the same process as the process of forming the first bit line 241.

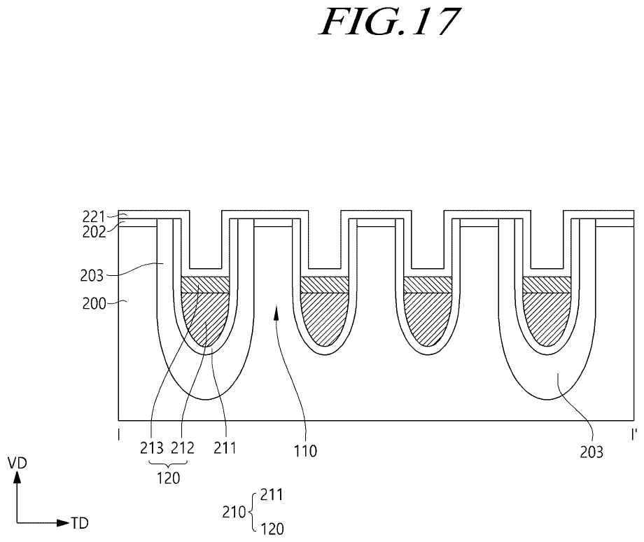

FIG. 17 to FIG. 20 are views illustrating another method for forming a memory device according to an embodiment of the present disclosure.

The structure illustrated in FIG. 17 may be formed by the same method as the method of forming the memory device described above with reference to FIG. 10 and FIG. 11.

Portions of the gate capping layer 221 described above with reference to FIG. 11 may be removed. More specifically, a portion of the gate capping layer 221 that is located on the second insulating layer 202 and a portion of the gate capping layer 221 that is located on the upper surface of the word line 120 are removed. According to an embodiment of the present disclosure, removing the portions of the gate capping layer 221 may include an etching process.

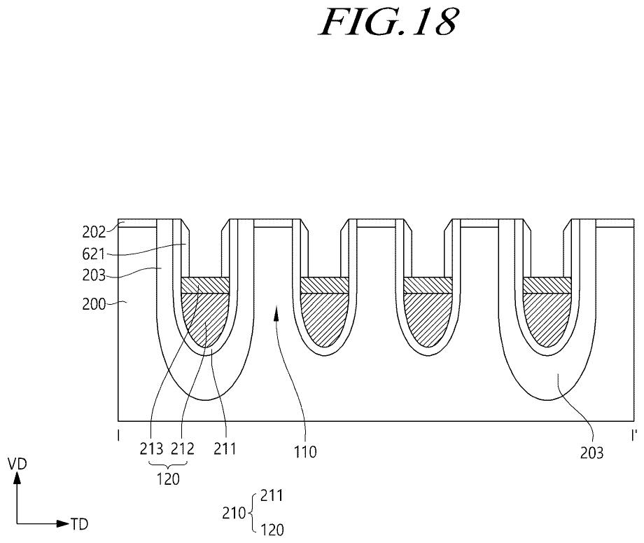

Referring to FIG. 18, following the etching process, the gate capping layer 621 may remain only on the inner side surfaces of the gate insulating layer 211. According to an embodiment of the present disclosure, the upper surface of the gate capping layer 621 may be located at the same level as the upper surface of the second insulating layer 202 or at a level lower than the upper surface of the second insulating layer 202 in the vertical direction.

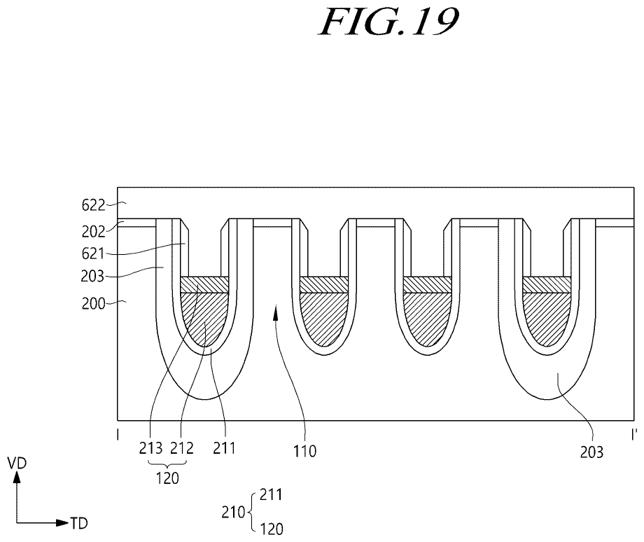

Referring to FIG. 19, a buffer layer 622 may be formed on the upper surfaces of the second insulating layer 202, the gate capping layer 621 and the word line 120. The buffer layer 622 may fill the space between the inner side surfaces of the gate capping layer 621. According to an embodiment of the present disclosure, the buffer layer 622 may include the same material as the second insulating layer 202.

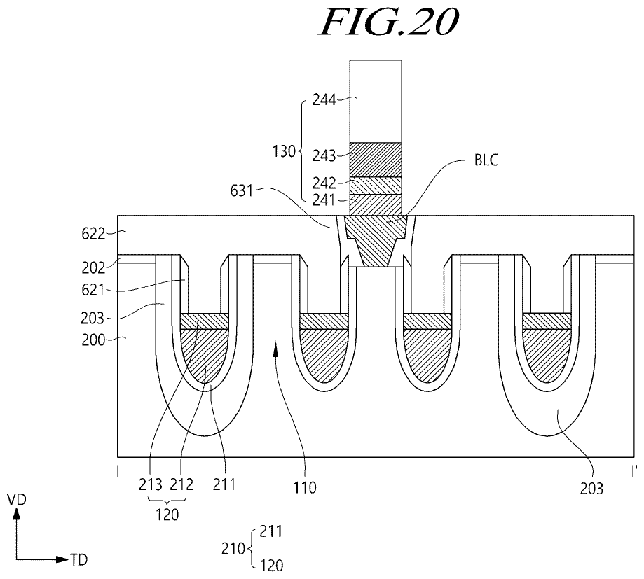

Referring to FIG. 20, a contact hole that passes through the buffer layer 222, the gate capping layer 221 and the second insulating layer 202 in the vertical direction may be formed. Forming the contact hole may include the same process as the process of forming the contact hole 1300 described above with reference to FIG. 13.

After the contact hole is formed, a first spacer 631 and a bit line contact BLC that fill the contact hole may be sequentially formed. Processes of forming the first spacer 631 and the bit line contact BLC may include the same processes as the processes of forming the first spacer 231 and the bit line contact BLC described above with reference to FIG. 14 and FIG. 15.

A bit line structure 130 may then be formed on the bit line contact BLC. Forming the bit line structure 130 may include the same process as forming the bit line structure 130 described above with reference to FIG. 15 and FIG. 16.

Referring again to FIG. 2, the gate capping layer 221 is disposed on the inner side surfaces of the gate insulating layer 211. The buffer layer 222 may be disposed on the gate capping layer 221. The bit line contact BLC may pass though the buffer layer 222 and the gate capping layer 221 in the vertical direction, and contacts the active area 110. According to an embodiment of the present disclosure, the bit line contact BLC and the first spacer 231 may be formed through a self-alignment etching method using the gate capping layer 221 and the buffer layer 222 as a mask. According to an embodiment of the present disclosure, the gate capping layer 221 may include nitride, and the buffer layer 222 may include oxide.

According to an embodiment of the present disclosure, a process of forming the bit line contact BLC may include a process of selectively etching the buffer layer 222. A process of selectively etching the buffer layer 222 may include an etching process using a material that may increase the etching selectivity between the gate capping layer 221 and the buffer layer 222. By selectively etching the buffer layer 222, at least a portion of the gate capping layer 221 around an area where the bit line contact BLC is to be located might not be etched when forming the bit line contact BLC. The gate capping layer 221 that remains without being etched may be located between the bit line contact BLC and the word line 120. As the gate capping layer 221 remains between the bit line contact BLC and the word line 120, a short that occurs when the bit line contact BLC and the word line 120 are close to each other upon forming the bit line contact BLC may be prevented.

According to an embodiment of the present disclosure, a process of forming the bit line structure 130 may include a process of etching the first bit line 241. The first bit line 241 may include a material that has an etch selectivity with respect to the buffer layer 222. Because the first bit line 241 includes a material that has an etching selectivity with respect to the buffer layer 222, at least a portion of the buffer layer 222 might not be etched when forming the first bit line 241. Therefore, it is possible to prevent process defects that may occur as layers located under the first bit line 241 are etched together when forming the first bit line 241 and due to residues remaining after etching.

While detailed embodiments are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. It should be understood that all changes within the meaning and range of equivalency of the claims are included within their scope. Furthermore, the embodiments may be combined to form additional embodiments.

What is claimed is:

1. A memory device comprising:
a substrate including an active area;
a word line embedded in the substrate, the word line crossing the active area;
a gate insulating layer surrounding a side surface and a lower surface of the word line;
a gate capping layer disposed on inner side surfaces of the gate insulating layer; and
a bit line contact contacting the active area that is disposed between word lines, the bit line contact having a side surface that faces the gate capping layer and is concave toward a center of the bit line contact.

2. The memory device according to claim 1, further comprising:
a buffer layer disposed on the gate capping layer,
wherein the buffer layer contacts an upper surface of the word line.

3. The memory device according to claim 1, wherein the gate capping layer covers an entirety of the upper surface of the word line.

4. The memory device according to claim 3, further comprising:
a buffer layer disposed on the gate capping layer,
wherein a lowermost surface of the buffer layer contacts the gate capping layer in an area between inner side surfaces of the gate capping layer.

5. The memory device according to claim 4, further comprising:
a spacer surrounding the side surface of the bit line contact,
wherein an outer side surface of the spacer contacts the buffer layer and the gate capping layer.

6. The memory device according to claim 5, wherein the lowermost surface of the buffer layer is located at a level lower than a lower surface of the bit line contact.

7. The memory device according to claim 1, wherein
the bit line contact includes a first section and a second section that is located on the first section and is continuous to the first section, and
an angle between a side surface of the first section and an upper surface of the substrate is different from an angle between a side surface of the second section and the upper surface of the substrate.

8. The memory device according to claim 1, wherein
the bit line contact includes a first section and a second section that is located on the first section and is continuous to the first section, and
wherein the area of an upper surface of the first section is smaller than the area of a lower surface of the second section.

9. The memory device according to claim 1, wherein the gate capping layer includes nitride, and the buffer layer includes oxide.

10. A memory device comprising:
a substrate including an active area;
a word line embedded in the substrate, and crossing the active area;
a gate insulating layer surrounding a side surface and a lower surface of the word line;
a gate capping layer disposed on inner side surfaces of the gate insulating layer on the word line;
a buffer layer disposed on the gate capping layer; and
a bit line contact including a first section that contacts the active area between word lines and a second section that is located on the first section and is continuous to the first section, wherein an angle formed by a side surface of the first section with an upper surface of the substrate is different from an angle formed by a side surface of the second section with the upper surface of the substrate.

11. The memory device according to claim 10, wherein a side surface of the bit line contact is concave toward a center of the bit line contact.

12. The memory device according to claim 11, wherein the buffer layer contacts an upper surface of the word line.

13. The memory device according to claim 11, wherein the buffer layer fills a space between inner side surfaces of the gate capping layer.

14. The memory device according to claim 11, wherein the gate capping layer covers entirety of the upper surface of the word line.

15. The memory device according to claim 11, wherein an angle between the side surface of the first section and the upper surface of the substrate is greater than an angle between the side surface of the second section and the upper surface of the substrate.

16. The memory device according to claim 11, wherein the area of an upper surface of the first section is smaller than the area of a lower surface of the second section.

17. A memory device comprising:
a substrate including an active area;
a bit line contact contacting the active area, having a side surface that is concave toward a center of the bit line contact, and including a first section and a second section that is located on the first section and is continuous to the first section;
a gate capping layer located on a side surface of the first section of the bit line contact; and
a buffer layer located on a side surface of the second section of the bit line contact.

18. The memory device according to claim 17, further comprising:
a word line embedded in the substrate, and crossing the active area; and
a gate insulating layer surrounding a side surface and a lower surface of the word line,
wherein the gate capping layer is disposed on inner side surfaces of the gate insulating layer.

19. The memory device according to claim 17, wherein the buffer layer fills a space between inner side surfaces of the gate capping layer.
